(19) United States
(12) Patent Application Publication
(10) Pub. No.: US 2019/0372002 A1
(43) Pub. Date: Dec. 5, 2019

(54) MANUFACTURING METHOD FOR MASK SHEET, VAPOR DEPOSITION MASK, AND DISPLAY PANEL

(71) Applicant: Sharp Kabushiki Kaisha, Sakai City, Osaka (JP)

(72) Inventor: Koji YAMABUCHI, Sakai City (JP)

(21) Appl. No.: 16/062,738

(22) PCT Filed: Sep. 14, 2016
(86) PCT No.: PCT/JP2016/077184

§ 371 Date: Jun. 15, 2018

(51) Int. Cl. H01L 51/00; H01L 51/56; C23C 14/04

(52) U.S. Cl. CPC H01L 51/0011; C23C 14/042; H01L 51/56

(57) ABSTRACT

A vapor deposition mask sheet including a grippable side end portion, and an intermediate portion including a valid portion with a plurality of vapor deposition holes formed in the valid portion and an edge portion surrounding the valid portion, wherein a plurality of recesses or a plurality of through-holes are formed in the edge portion.

### TECHNICAL FIELD

The present invention relates to a mask sheet for vapor deposition and the like.

### BACKGROUND ART

For example, in the process of manufacturing Organic Light-Emitting Diode (OLED) panels, patterns of an organic material corresponding to a plurality of vapor deposition holes are formed by depositing an organic material on a substrate through a vapor deposition mask with a plurality of vapor deposition holes.

Vapor deposition masks may be manufactured by fixing a plurality of mask sheets to a frame body in a stretched state. In PTL 1, ribs are provided surrounding a valid portion (a vapor deposition portion on which vapor deposition holes are formed) of the mask sheet to increase the rigidity of the mask sheet.

### CITATION LIST

### Patent Literature

PTL 1: JP 2012-132096 A (Publication Date: Jul. 12, 2012)

### SUMMARY OF INVENTION

### Technical Problem

As in PTL 1, when ribs are provided surrounding the valid portion, a valid portion having low rigidity and a portion having high-rigidity surrounding the valid portion are generated in the mask sheet. As illustrated in the example of FIG. 13, this causes problems that the mask sheet deforms when tension is applied.

### Solution to Problem

The mask sheet according to an embodiment of the present invention is a mask sheet for vapor deposition including grippable side end portions, and an intermediate portion including a valid portion with a plurality of vapor deposition holes formed in the valid portion and an edge portion surrounding the valid portion,

wherein a plurality of recesses or a plurality of through-holes are formed in the edge portion.

### Advantageous Effects of Invention

The problems that the mask sheet deforms when tension is applied can be improved.

### BRIEF DESCRIPTION OF DRAWINGS

FIG. 1A is a flowchart illustrating a manufacturing method of an Organic Light-Emitting Diode (OLED) panel, and FIG. 1B is a cross-sectional view illustrating a configuration of an OLED panel.

FIG. 2 is a schematic view illustrating a vapor depositing of manufacturing an OLED panel.

FIG. 3 is a plan view illustrating a configuration of a mask sheet according to a first embodiment.

FIGS. 4A to 4D illustrate a first embodiment. FIG. 4A is a plan view of a vapor deposition mask including a mask sheet, FIG. 4B is a plan view illustrating a stretch method of a mask sheet, FIG. 4C is a cross section C-C in FIG. 4A, and FIG. 4D is a cross section F-F in FIG. 4A.

FIG. 5 is a flowchart illustrating a manufacturing method of a vapor deposition mask.

FIGS. 6A to 6C illustrate a first embodiment. FIG. 6A is a plan view of a mask sheet, FIG. 6B is a cross section A-A in FIG. 6A, and FIG. 6C is a cross section B-B in FIG. 6A.

FIGS. 7A to 7C illustrate a first embodiment. FIG. 7A is a plan view of a mask sheet, FIG. 7B is a cross section C-C in FIG. 7A, and FIG. 7C is a cross section D-D in FIG. 7A.

FIGS. 8A and 8B describe a concept of an average thickness applied to a mask sheet. FIGS. 8A and 8B are cross-sectional views of valid portions, FIG. 8C and 8D are cross-sectional views of an edge portion, FIG. 8E is a plan view of a valid portion, and FIG. 8F is a plan view of an edge portion.

FIGS. 9A to 9D illustrate a modified example of the first embodiment. FIG. 9A is a plan view of a mask sheet, FIG. 9B and 9C are cross sections of edge portions, and FIG. 9D is a plan view of an edge portion.

FIG. 10 is a plan view illustrating a configuration of a mask sheet according to a second embodiment.

FIG. 11A is a plan view illustrating a valid portion of a mask sheet according to a second embodiment, FIG. 11B is a plan view illustrating an edge portion of the mask sheet, and FIG. 11C is a plan view illustrating a configuration of a vapor deposition mask according to the second embodiment.

FIGS. 12A to 12C illustrate a modified example of the second embodiment, and FIG. 12A to 12C are plan views of a mask sheet.

FIG. 13 is a plan view illustrating the problems of conventional mask sheets.

### DESCRIPTION OF EMBODIMENTS

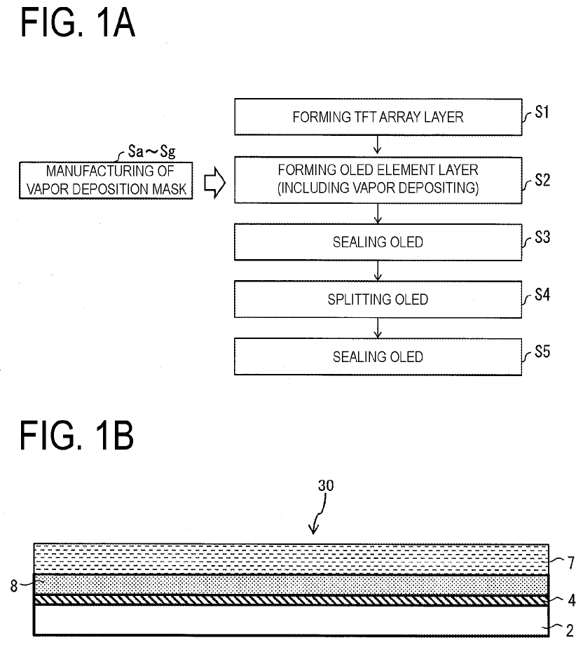

Hereinafter, an embodiment of the present invention is described with FIGS. 1A to FIG. 13.

FIG. 1A is a flowchart illustrating an outline of a manufacturing method of an Organic Light-Emitting Diode (OLED) panel, and FIG. 1B is a cross-sectional view illustrating a configuration of an OLED panel. As illustrated in FIGS. 1A and 1B, a TFT array layer 4 (for example including a thin film transistor, a signal line and the like) is formed on a substrate 2 in step S1. In step S2, an OLED element layer 8 (for example including an electrical functional layer, a light-emitting layer, a negative pole and the like) is formed using a vapor deposition mask.

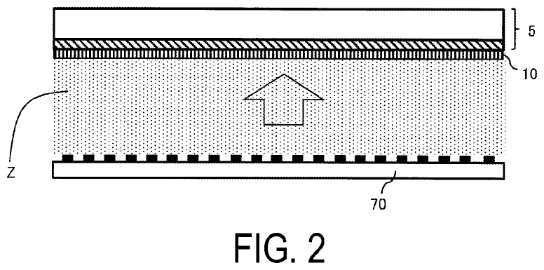

In this vapor depositing, as depicted in FIG. 2, for example, a mask including a mask sheet 10 with a plurality of through-holes may be adhered to a substrate 5 that includes a TFT array layer, and vapor deposition particles Z (for example, organic light-emitting materials) vaporized or sublimated by a vapor deposition source 70 may be vapor-deposited on the substrate 5 under vacuum conditions through the mask sheet 10 to form vapor deposition patterns with the pattern corresponding to the through-holes of the mask sheet 10.

In step S3, the OLED element layer 8 is sealed by protective glass 7 or the like, and in step S4 the OLED element layer 8 is divided (cut into individual pieces) and is formed as an OLED panel 30. Note that rigidity in step S5, the OLED panel 30 implements a drive driver, a polarization plate, a touch panel and the like.

### First Embodiment

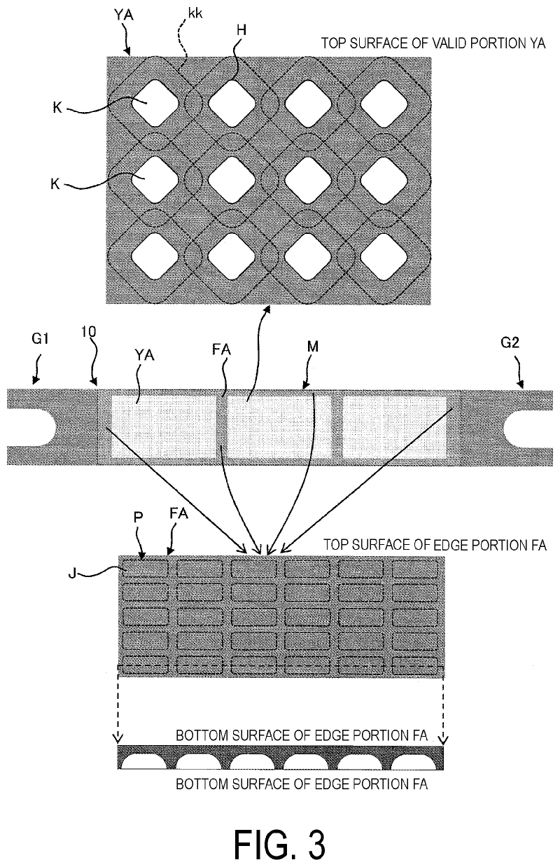

FIG. 3 is a plan view illustrating a configuration of a mask sheet according to a first embodiment. As illustrated in FIG. 3, a mask sheet 10 according to the first embodiment may be strip-shaped, and may be made of, for example, Invar material with a thickness of from 10 μm to 50 μm. Note that, a lower surface of the mask sheet 10 is opposed to the vapor deposition source 70 in FIG. 2, and an upper surface of the mask sheet 10 is opposed to the substrate 5 in FIG. 2.

The mask sheet 10 includes two grippable side end portions G1 and G2 and an intermediate portion M. The intermediate portion M are composed of a plurality of valid portions YA aligned in a longitudinal direction, and an edge portion FA surrounding the valid portions YA. In the valid portion YA, a plurality of vapor deposition holes H are formed, and each valid portion corresponds to a display area of one OLED panel. In other words, vapor deposition particles generated from the vapor deposition source are deposited on the display areas of the substrate after passing through vapor deposition holes H. The edge portion FA overlaps with a non-display area (a frame area) surrounding the display area of the substrate, and the vapor deposition particles are blocked by the edge portion FA and do not reach the non-display area.

In the first embodiment, in order to equalize the rigidity of the intermediate portion M, as illustrated in FIG. 3, after aligning the maximum thickness of the valid portion YA and the edge portion FA to the thickness of the base material, a plurality of recesses P may be formed by half etching over the entire region of the lower surface of the edge portion FA. FIG. 3 is viewed from the upper surface of the mask sheet, and an opening K of the vapor deposition hole H is formed on the upper surface of the valid portion YA. The vapor deposition hole H has a shape in which cross-sections parallel to the sheet surface gradually become larger from the opening K on the upper surface to the lower surface, and the opening kk of the lower surface (an area of lower surface etching) is greater than the opening K of the upper surface (described later). In FIG. 3, in the intermediate portion M, a process which will be described later may be applied to the edge portion FA such that the rigidity of the valid portion YA and the edge portion FA is constant.

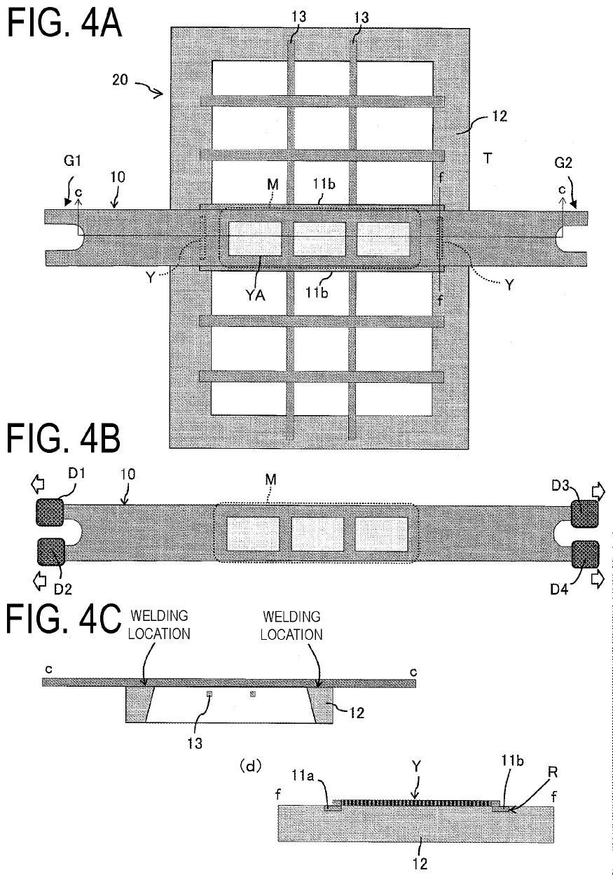

FIGS. 4A to 4D illustrate the first embodiment. FIG. 4A is a plan view of a vapor deposition mask including a mask sheet, FIG. 4B is a plan view illustrating a stretch method of a mask sheet, FIG. 4C is a cross section C-C in FIG. 4A, and FIG. 4D is a cross section F-F in FIG. 4A. As illustrated in FIGS. 4A to 4D, a vapor deposition mask 20 according to the first embodiment is composed of a frame (a frame body) 12, a plurality of support sheets 13 placed over the vertical direction (width direction of the mask sheet) of the frame 12, a plurality of cover sheets 11A and 11B placed over the horizontal direction (longitudinal direction of the mask sheet) of the frame 12, and a plurality of mask sheets 10. In FIGS. 4A to 4D, for convenience of explanation, only one mask sheet 10 is illustrated, but in practice, a number of mask sheets 10 corresponding to the number of rows of arranged panels may be provided.

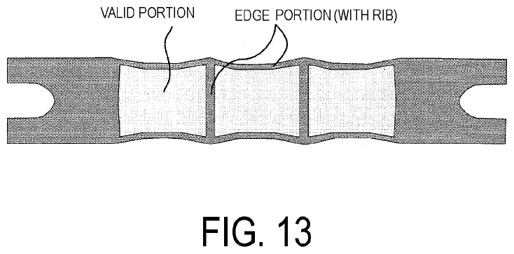

In conventional mask sheets, as the edges FA are not processed like the recesses P and there are valid portions with low rigidity and edge portions (with ribs) with high rigidity, the mask sheet may deform as illustrated in FIG. 13 when tension is applied. However, in the first embodiment, because the rigidity of the edge portion FA is aligned with the rigidity of the valid portion YA by providing the recesses P in the edge portion FA as illustrated in FIG. 4B, deformation of the intermediate portion M (in particular, the valid portion YA) is suppressed when tension is applied, and both shape correction and position correction may be easily applied to the mask sheet.

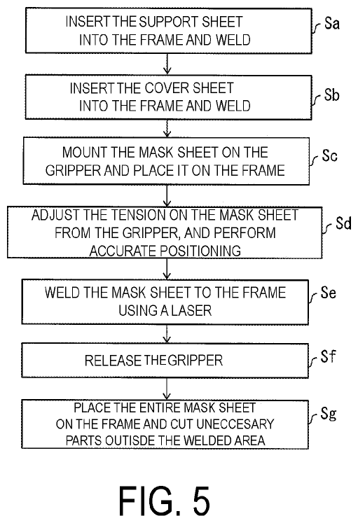

A manufacturing method of the vapor deposition mask is depicted in FIG. 5. As illustrated in FIGS. 4A, 4B and FIG. 5, each of end portions of the support sheet 13 are inserted into the recesses provided in the frame 12 and are welded (step Sa). Furthermore, each of end portions of the cover sheets 11A and 11B is inserted into the recesses R provided in the frame 12 such that each of the end portion is not exposed from the openings, and welded (step Sb). Next, both side end portions G1 and G2 of the mask sheets 10 are set in grippers D1 to D4 and arranged on the mask frame to overlap with the cover sheets 11 (step Sc). As illustrated in FIGS. 4A and 4B. each of the side end portions G1 and G2 may have a shape in which the central portion is cut out. The portions located on both sides of the cutout of the side end portion G1 may be sandwiched between the grippers D1 and D2, and the portions located on both sides of the cutout of the side end portion G2 may be sandwiched between the grippers D3 and D4.

The grippers D1 to D4 apply tension to the mask sheet, and the position of the mask sheet 10 is aligned to the frame 12 by individually adjusting each gripper D1 to D4 (step Sd). In this step, the position of the opening K of the vapor deposition hole H in the valid portion YA of the mask sheet 10 is aligned to a pixel area (a light-emitting area) of the substrate 5. However, this position alignment is difficult when the deformation of the valid portion YA is great.

After the position alignment is completed, the welding portion Y of the mask sheet 10 is welded to the frame 12 by using a laser (step Se). In particular, a plurality of spots may be welded. In this way, as illustrated in FIG. 4C and 4D, a plurality of welded spots may be formed by melting of the mask sheet 10 and the frame 12. After welding is completed, grippers D1 to D4 of both side end portions G1 and G2 are released, and an outside part of the welding portion Y of the mask sheet 10 (an unnecessary portion) may be cut (step Sg).

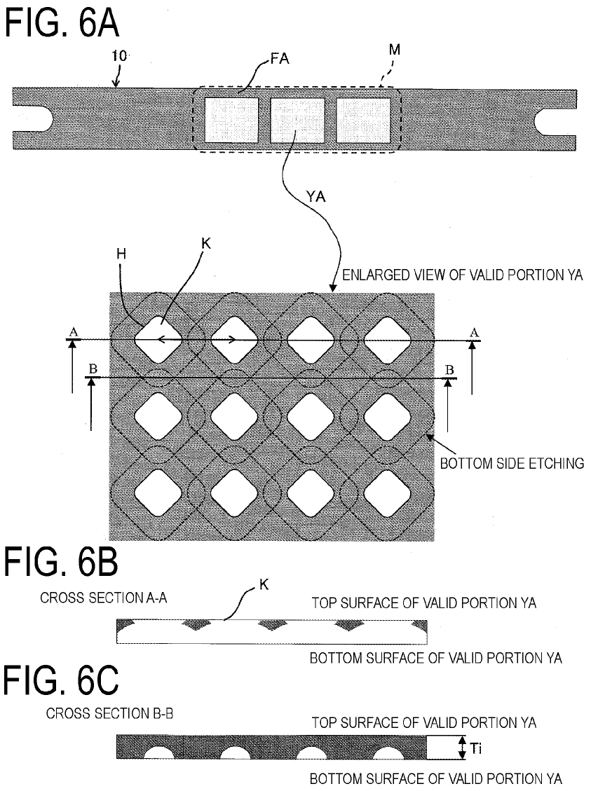

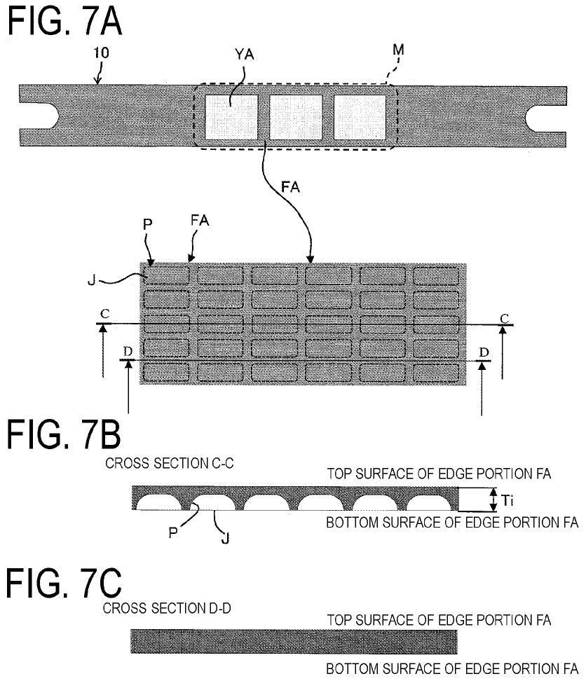

FIGS. 6A to 6C illustrate the first embodiment, FIG. 6A is a plan view of a mask sheet, FIG. 6B is a cross section A-A in FIG. 6A, and FIG. 6C is a cross section B-B in FIG. 6A. FIGS. 7A to 7C illustrate the first embodiment, FIG. 7A is a plan view of a mask sheet, FIG. 7B is a cross section C-C in FIG. 7A, and FIG. 7C is a cross section D-D in FIG. 7A.

The mask sheet may be formed as described below, for example. First, a negative or a positive photosensitive resist material is coated on both sides of a long plate which is made of an Invar material, and resist films are formed over both surfaces (the upper and lower surfaces).

The resist films on the upper and lower surfaces are exposed and developed using exposure masks, thereby forming resist patterns on both sides of the sheet. With the upper surface resist pattern as a mask, the upper surface of the valid portion YA is etched (the upper surface of the edge portion FA is not etched), and the opening pattern portion K is formed on the upper surface of the valid portion YA (which does not become a perforated vapor deposition hole in this step). The upper surface is covered by a resistant resin which resists etching, and both the valid portion YA and the lower surface of the edge portion FA are etched with the lower surface resist pattern as a mask. Accordingly, a vapor deposition hole H (a through-hole) is formed by corrosion from the lower surface in the valid portion YA, and a plurality of recesses P may be formed on the lower surface of the edge portion FA.

As illustrated in FIGS. 6A to 6C, a plurality of vapor deposition holes H in the valid portion YA may be formed in a matrix shape in the longitudinal direction and the width direction of the sheet, and the opening K (the opening of the upper surface) may be formed either in a rectangular shape having round corners or in a circular shape such that the shape of opening K corresponds to the pixel area of the substrate. In the valid portion YA, by performing the etching of each vapor deposition hole on the lower surface wider and deeper than the upper surface, the shadowed portion (the height of the boundary between two adjacent vapor deposition holes) is reduced, increasing both the efficiency and the accuracy of vapor deposition on substrates.

In the valid portion YA, when a cross section is taken along the A-A line connecting the centers of two openings K adjacent in the horizontal direction as illustrated in FIG. 6B, the base material has a minimum structure (the hollow is at maximum). When a cross section is taken along the B-B line parallel to the A-A line and passing through points equidistant from two openings K adjacent in the vertical direction as illustrated in FIG. 6C, the base material has a maximum configuration (the hollow is at minimum (the maximum thickness of the base material is Ti).

In contrast, as illustrated in FIGS. 7A to 7C, a plurality of recesses P on the lower surface on the edge portion FA may be formed in a matrix shape in the longitudinal direction and the width direction of the sheet, and openings J of the recesses P are, for example, formed in the shape of a rectangle having round corners. Note that the openings J may have a shape such a square, a rectangle, a rhombus, a circle, or an ellipse.

As described above, the recess P may be formed by performing lower surface etching, and when a cross section is taken along the C-C line connecting the centers of two adjacent openings J, its diameter gradually decreases toward the upper surface (the maximum thickness is the thickness of the base material Ti), as illustrated in FIG. 7B. Note that, in a cross section taken along the D-D line which does not pass through any opening J, the base material may remain as illustrated in FIG. 7C.

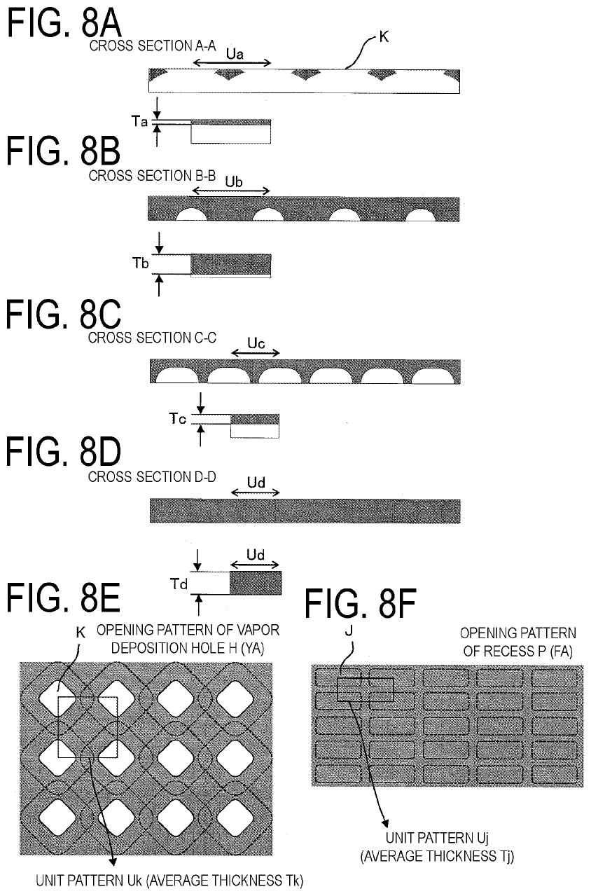

FIGS. 8A to 8F describe a concept of an average thickness on a mask sheet, where FIGS. 8A and 8B are cross-sectional views of valid portions, FIGS. 8C and 8D are cross-sectional views of an edge, FIG. 8E is a plan view of a valid portion, and FIG. 8F is a plan view of an edge.

As illustrated in FIGS. 6A to 8F, when a line segment connecting the centers of two openings K adjacent in the horizontal direction (the longitudinal direction of the mask sheet) is a unit line Ua, a line segment on the B-B line which is same length as the unit line Ua is a unit line Ub, a line segment connecting the centers of two openings J adjacent in the horizontal direction (longitudinal direction of the mask sheet 10) on the edge portion FA is a unit line Uc, and a line segment on the D-D line which is the same length as the unit line Uc is a unit line Ud, then, the cross section of the A-A line is a repetition of the unit line Ua, the cross section of the B-B line is a repetition of the unit line Ub, the cross section of the C-C line is a repetition of the unit line Uc, and the cross section of the D-D line is a repetition of the unit line Ud.

In the first embodiment, in order to equalize the rigidity of the valid portion YA and the edge portion FA, an average thickness of a cross section including the unit line Ua (an integrated value of thickness along Ua divided by a length of Ua) is Ta, an average thickness of a cross section including the unit line Ub (an integrated value of thickness along Ub divided by a length of Ub) is Tb, an average thickness of a cross section including the unit line Uc (an integrated value of thickness along Uc divided by a length of Uc) is Tc, and an average thickness of a cross section including the unit line Ud (an integrated value of thickness along Ud divided by a length of Ud) is Td. Accordingly, Ta<Tc and Tb<Td. Furthermore, Ta<Tc<Tb and Td.

In addition, the opening pattern of a vapor deposition hole in FIG. 8C is structured by a repetition of the unit pattern Uk (the pattern which is defined by a square shape obtained by connecting the centers of four neighboring openings in the longitudinal and horizontal directions in the valid portion YA), and the opening pattern of a recess in FIG. 8D is structured by a repetition of the unit pattern Uj (the pattern which is defined by a rectangle shape obtained by connecting the centers of four neighboring openings in the longitudinal and horizontal directions in the edge portion FA).

In order to equalize the rigidity of the valid portion YA and the edge portion FA, it is preferable that a ratio of the area occupied by the openings J of the recesses in the unit pattern Uj of the edge portion FA>a ratio of the area occupied by the openings K of the vapor deposition holes in the unit pattern Uk of the valid portion YA.

In addition, to equalize the rigidity of the valid portion YA and the edge portion FA, it is preferable that the average thickness of a portion corresponding to a unit pattern Uj of the edge portion FA (an integral value of the thickness in Uj divided by the area of Uj) is Tj (see FIG. 8F), and that Ta<Tj<Tb.

To further equalize the rigidity of the valid portion YA and the edge portion FA, it is preferable that the average thickness of the portion corresponding to the unit pattern Uk of the valid portion YA is Tk (an integral value of the thickness in Uk divided by the area of Uk, see FIG. 8E), and that Tk=Tj (Tk and Tj are substantially equivalent).

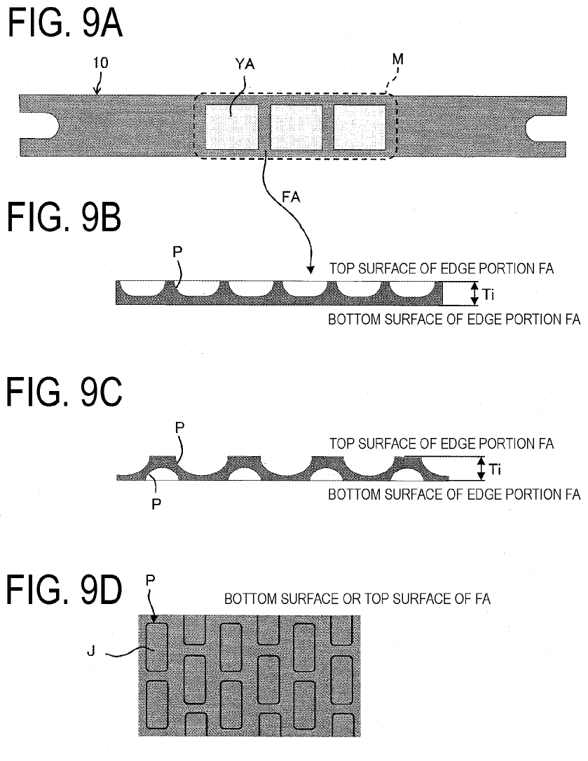

FIGS. 9A to 9D illustrate a modified example of the first embodiment, FIG. 9A is a plan view of a mask sheet, FIG. 9B and 9C are cross sections of edges, and FIG. 9D is a plan view of an edge. In the first embodiment, as illustrated in FIG. 9B, recesses P may be provided over the entire region of upper surface area of the edge portion FA, and as in FIG. 9C, recesses P may be provided over the entire region of both the upper surface and the lower surface of the edge portion FA. As illustrated in FIG. 9D, the opening pattern of the recesses provided in at least one of the upper surface or the lower surface of the edge portion FA may be a checkered shape to increase the rigidity of the edge portion FA.

### Second Embodiment

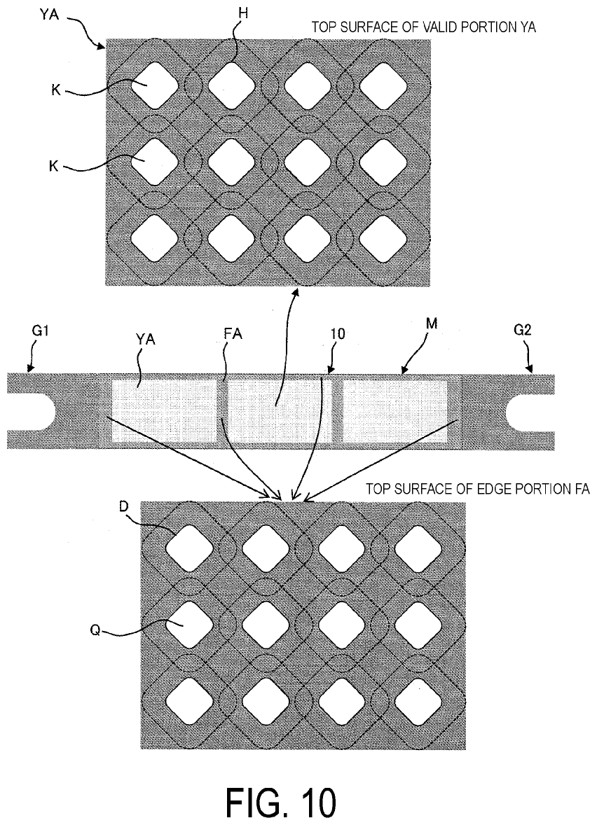

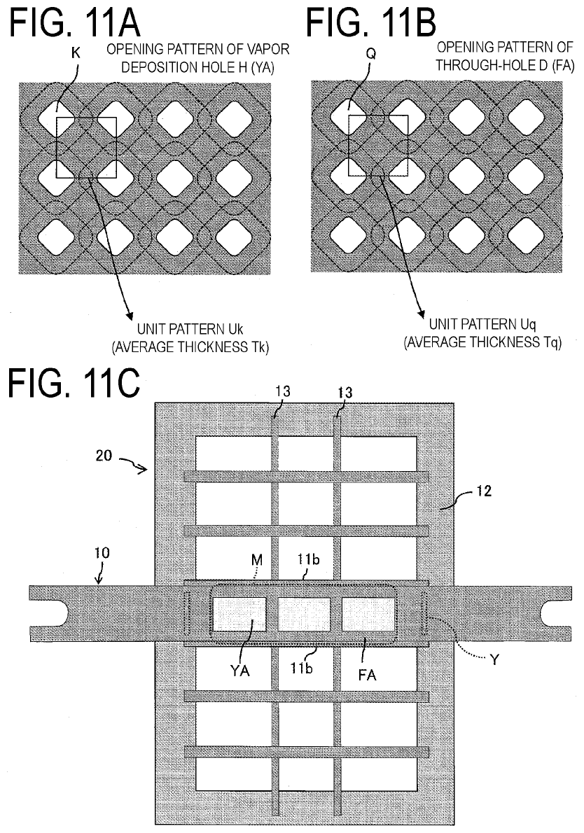

FIG. 10 is a plan view illustrating a configuration of a mask sheet according to a second embodiment, where FIG. 11A is a plan view illustrating a valid portion of a mask sheet according to the second embodiment, FIG. 11B is a plan view illustrating an edge of the mask sheet, and FIG. 11C is a plan view illustrating a configuration of a vapor deposition mask according to the second embodiment.

In the second embodiment, as illustrated in FIG. 10, after aligning the maximum thickness of the valid portion YA and the edge portion FA to the thickness of the base material, a plurality of the through-holes D similar to the plurality of vapor deposition holes H of the valid portion YA may be formed over the entire region of edge portion FA. Herein, a plurality of the through-holes D may be formed on the edge portion FA by performing the same double-side etching as the valid portion YA.

As illustrated FIG. 11A and 11B, on the upper surface of the intermediate portion of the mask sheet 10, the opening pattern of the vapor deposition hole H on the valid portion YA and the opening pattern of the through-hole D of the edge portion YA are identical. In other words, the opening pattern of the through-hole of FIG. 11B is structured by repetition of a unit pattern Uq (a pattern which is defined by a square shape obtained by connecting the centers of four neighboring openings in the vertical direction and the horizontal direction in the edge portion FA), and an average thickness of the portion corresponding to the unit pattern Uq of the edge portion FA (an integrated value of thickness in Uq divided by an area of Uq) is Tq, where Tq=Tk (Tq and the average thickness Tk of the portion corresponding to the unit pattern Uk of the valid portion YA are substantially equivalent). In addition, Ta <Tq<Tb (see FIG. 8A and 8B). In this way, the rigidity of the intermediate portion M can be made uniform.

Note that in the second embodiment, as it is necessary to cover the plurality of through-holes D of the edge portion FA, as illustrated in FIG. 11C in the vapor deposition mask 20, by appropriately adjusting the widths of the cover sheets 11a and 11b and the support sheet 13, the cover sheets 11A and 11B may be provided in the longitudinal direction of the mask sheet 10 to shield the longitudinal portion of the edge portion FA, and the support sheet 13 may be provided in the width direction to shield the width direction portion of the edge portion FA.

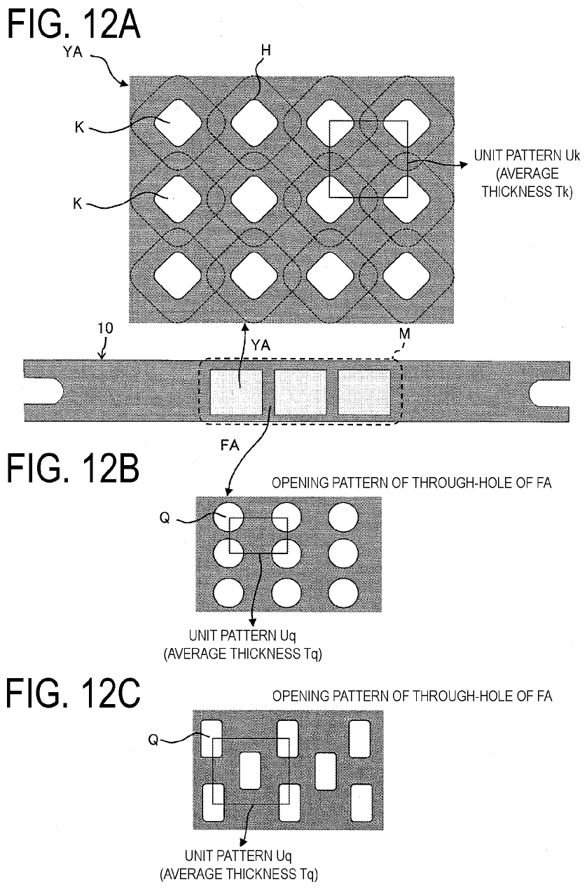

FIGS. 12A to 12C illustrate a modified example of the second embodiment. FIG. 12A to 12C are plan views of the mask sheet. In the second embodiment, the opening pattern of the vapor deposition hole H of the valid portion YA and the opening pattern of the through-hole D of the edge portion YA may be different. For example, as in FIG. 12B, the opening Q of the through-holes may be circular. In this case, it may be preferable that the average thickness Tk of the portion corresponding to the unit pattern Uk of the valid portion YA=the average thickness Tq of the portion corresponding to the unit pattern Uq of the edge portion FA. In addition, as in FIG. 12C, it is also possible to adjust the rigidity of the edge portion FA by making the opening pattern of the through-holes a checkered pattern. In this case, it may be preferable that the average thickness Tk of the portion corresponding to the unit pattern Uk of the valid portion YA=the average thickness Tq of the portion corresponding to the unit pattern Uq of the edge portion FA.

### Supplement

The mask sheet according to a first aspect of the present invention is a mask sheet for vapor deposition including grippable side end portions (G1), and an intermediate portion (M) including a valid portion (YA) with a plurality of vapor deposition holes (H) formed in the valid portion (YA) and an edge portion (FA) surrounding the valid portion, wherein a plurality of recesses (P) or a plurality of through-holes (D) are formed in the edge portion.

In a second aspect, an opening pattern of the plurality of vapor deposition holes is structured by repetition of a first unit pattern (Uk) and an opening pattern of the plurality of recesses is structured by repetition of a second unit pattern (Uj); and an area ratio occupied by the opening of the recesses in the second unit pattern is greater than an area ratio occupied by the opening of the vapor deposition holes in the first unit pattern.

In a third aspect, a line segment connecting centers of the openings of two adjacent vapor deposition holes is defined as an opening line (Ua), and a line segment with a same length as the opening line does not pass through the opening of the vapor deposition holes is defined as a gap line (Ub); and an average thickness (Tj) of a portion corresponding to the second unit pattern of the edge portion is less than an average thickness (Tb) of a cross section including the gap line.

In a fourth aspect, the average thickness (Tj) of the portion corresponding to the second unit pattern is greater than the average thickness (Ta) of a cross section including the first opening line.

In a fifth aspect, an average thickness (Tk) of a portion corresponding to the first unit pattern of the valid portion and the average thickness (Tj) of the portion corresponding to the second unit pattern of the edge portion are equal.

In a sixth aspect, a line segment connecting centers of the openings of two adjacent recesses is defined as a second opening line (Uc), and a line segment with a same length as the second opening line does not pass through the recess opening is defined as a second gap line (Ud); and an average thickness (Ta) of a cross section including the first opening line is less than an average thickness (Tc) of a cross section including the second opening line, which is less than an average thickness (Tb) of a cross section including the first gap line, and is the average thickness (Td) of the cross section including the second gap line.

In a seventh aspect, a surface facing a vapor deposition source is defined as a lower surface, and the plurality of recesses are formed on the lower surface of the edge portion.

In an eighth aspect, a surface facing a vapor deposition source is defined as a lower surface, and the plurality of recesses are formed over the entire region of at least one of an upper surface or the lower surface of the edge portion.

In a ninth aspect, a maximum thickness of the edge portion is equal to a maximum thickness of the effective portion.

In a tenth aspect, the opening pattern of the plurality of recesses or the opening pattern of the plurality of through-holes has a checkered-shape.

In an eleventh aspect, a surface facing a vapor deposition source is defined as a lower surface, and a plurality of vapor deposition holes with separate openings on an upper surface of the valid portion communicate with each other at the lower surface of the valid portion.

In a twelfth aspect, the opening pattern of the plurality of vapor deposition holes is structured by repeating the first unit pattern and the opening pattern of the plurality of through-holes is structured by repetition of the third unit pattern (Uq); and an area ratio occupied by the openings of the through-holes in the third unit pattern is equal to the area ratio occupied by the opening of the vapor deposition holes in the first unit pattern.

In a thirteenth aspect, the plurality of through-holes are formed throughout the edge portion.

In a fourteenth aspect, the opening pattern of the plurality of vapor deposition holes and an opening pattern of the plurality of through-holes are identical.

A vapor deposition mask of a fifteenth aspect includes the mask sheet (10); a frame body (12); and a cross-linked sheet (11) crossing the frame body, wherein the mask sheet is fixed to the frame body such that the edge portion overlaps with the cross-linked sheet.

In a sixteenth aspect, the plurality of through-holes overlap with the cross-linked sheet.

A seventeenth aspect of a method for manufacturing a display panel of includes vapor depositing using the vapor deposition mask.

The present invention is not limited to each of the embodiments stated above, and various modifications may be implemented within a range not departing from the scope of the claims. Embodiments obtained by appropriately combining technical approaches stated in each of the different embodiments also fall within the scope of the technology of the present invention. Moreover, novel technical features may be formed by combining the technical approaches stated in each of the embodiments.

### REFERENCE SIGNS LIST

10 Mask Sheet
11a,
11b
Cover sheet
12 Frame
20 Vapor deposition mask
30 Organic Light-Emitting Diode (OLED) panel (Display panel)
M Intermediate portion of mask sheet
G1, G2 Side end portion of mask sheet
D1 to D4 Gripper
YA Valid portion
FA Edge portion
P Recess
J Opening of recess
H Vapor deposition hole
K Opening of vapor deposition hole
D Through-hole
Q Opening of through-hole

1. (canceled)

2. A mask sheet for vapor deposition, the mask sheet comprising:
a grippable side end portion; and
an intermediate portion including a valid portion with a plurality of vapor deposition holes formed in the valid portion and an edge portion surrounding the valid portion,
wherein a plurality of recesses or a plurality of through-holes are formed in the edge portion,
wherein an opening pattern of the plurality of vapor deposition holes is structured by repetition of a first unit pattern and
an opening pattern of the plurality of recesses is structured by repetition of a second unit pattern, and
an area ratio occupied by the opening of the recesses in the second unit pattern is greater than an area ratio occupied by the opening of the vapor deposition holes in the first unit pattern.

3. The mask sheet according to claim 2,
wherein a line segment connecting centers of the openings of two adjacent vapor deposition holes is defined as a first opening line, and
a line segment with a same length as the first opening line does not pass through the opening of the vapor deposition holes is defined as a first gap line; and
an average thickness of a portion corresponding to the second unit pattern of the edge portion is less than an average thickness of a cross section including the first gap line.

4. The mask sheet according to claim 3,
wherein the average thickness of the portion corresponding to the second unit pattern is greater than the average thickness of a cross section including the first opening line.

5. The mask sheet according to claim 2,
wherein an average thickness of a portion corresponding to the first unit pattern of the valid portion and the average thickness of the portion corresponding to the second unit pattern of the edge portion are equal.

6. The mask sheet according to claim 3,
wherein a line segment connecting centers of the openings of two adjacent recesses is defined as a second opening line, and
a line segment with a same length as the second opening line that does not pass through the recess opening is defined as a second gap line, and
an average thickness of a cross section including the first opening line is less than an average thickness of a cross section including the second opening line, which is less than an average thickness of a cross section including the first gap line, and is an average thickness of the cross section including the second gap line.

7. The mask sheet according to claim 2,
wherein a surface facing a vapor deposition source is defined as a lower surface, and
the plurality of recesses are formed on the lower surface of the edge portion.

8. The mask sheet according to claim 2,
wherein a surface facing a vapor deposition source is defined as a lower surface, and
the plurality of recesses are formed over the entire region of at least one of an upper surface or the lower surface of the edge portion.

9. The mask sheet according to claim 2,
wherein a maximum thickness of the edge portion is equal to a maximum thickness of the effective portion.

10. The mask sheet according to claim 1,
wherein the opening pattern of the plurality of recesses or the opening pattern of the plurality of through-holes has a checkered-shape.

11. The mask sheet according to claim 2,
wherein a surface facing a vapor deposition source is defined as a lower surface, and
a plurality of vapor deposition holes with separate openings on an upper surface of the valid portion communicate with each other at the lower surface of the valid portion.

12. The mask sheet according to claim 2,
wherein the opening pattern of the plurality of vapor deposition holes is structured by repeating the first unit pattern,
the opening pattern of the plurality of through-holes is structured by repetition of the third unit pattern, and
an area ratio occupied by the openings of the through-holes in the third unit pattern is equal to the area ratio occupied by the opening of the vapor deposition holes in the first unit pattern.

13. The mask sheet according to claim 2,
wherein the plurality of through-holes are formed throughout the edge portion.

14. The mask sheet according to claim 2,
wherein the opening pattern of the plurality of vapor deposition holes and an opening pattern of the plurality of through-holes are identical.

15. A vapor deposition mask comprising:
the mask sheet according to claim 2;
a frame body; and
a cross-linked sheet crossing the frame body,
wherein the mask sheet is fixed to the frame body such that the edge portion overlaps with the cross-linked sheet.

16. The vapor deposition mask according to claim 15, wherein the plurality of through-holes overlap with the cross-linked sheet.

17. (canceled)

18. A mask sheet for vapor deposition, the mask sheet comprising:
a grippable side end portion;
an intermediate portion comprising a valid portion with a plurality of vapor deposition holes formed in the valid portion and an edge portion surrounding the valid portion,
wherein a plurality of recesses or a plurality of through-holes are formed in the edge portion,
an opening pattern of the plurality of vapor deposition holes is structured by repetition of a first unit pattern and an opening pattern of the plurality of recesses is structured by repetition of a second unit pattern, and
an area ratio occupied by the opening of the through-holes in the third unit pattern is equal to the area ratio occupied by the opening of the vapor deposition holes in the first unit pattern.

19. The mask sheet according to claim 18,
wherein the plurality of through-holes are formed throughout the edge portion.

20. The mask sheet according to claim 18,
wherein the opening pattern of the plurality of vapor deposition holes and the opening pattern of the plurality of through-holes are identical.

21. A vapor deposition mask comprising:
the mask sheet according to claim 18;
a frame body; and
a cross-linked sheet crossing the frame body,
wherein the mask sheet is fixed to the frame body such that the edge portion overlaps with the cross-linked sheet.

22. The vapor deposition mask according to claim 21,
wherein the plurality of through-holes overlap with the cross-linked sheet.
